(19) United States
(12) Patent Application Publication
(10) Pub. No.: US 2017/0205655 A1
(43) Pub. Date: Jul. 20, 2017

(54) DISPLAY SUBSTRATE, MANUFACTURING METHOD THEREOF AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Na LI, Beijing (CN); Kun JIANG, Beijing (CN); Ruichen ZHANG, Beijing (CN)

(21) Appl. No.: 15/227,314

(22) Filed: Aug. 3, 2016

(30) Foreign Application Priority Data
Jan. 18, 2016 (CN) 201610031519.5

(51) Int. Cl. G02F 1/1343; H01L 27/12; G02F 1/1333; G02F 1/1368; G02F 1/1362

(52) U.S. Cl. CPC G02F 1/13439; G02F 1/134309; G02F 1/1368; G02F 1/136286; G02F 1/133345; H01L 27/1259; H01L 27/124; H01L 27/1248; G02F 2001/134372; G02F 2001/136295; G02F 2201/123; G02F 2201/121

(57) ABSTRACT

A display substrate, a manufacturing method thereof and a display device are provided. The display substrate includes: a base substrate; first electrodes formed on the base substrate; a first insulating layer formed on the base substrate provided with the first electrodes; and second electrodes formed on the base substrate provided with the first insulating layer, at least one curved slit being formed in each of the second electrodes.

### TECHNICAL FIELD

The present invention relates to a display substrate, a manufacturing method thereof and a display device.

### BACKGROUND

With the continuous development of display technology, display devices such as thin-film transistor liquid crystal displays (TFT-LCDs) are widely applied in the display fields of TV, computer, mobile phone, etc.

The display device may include a fringe filed switching (FFS) mode display device. The FFS mode display device generally comprises an array substrate and a color filter (CF) substrate which are cell-assembled, and a liquid crystal layer filled between the array substrate and the CF substrate. The liquid crystal layer is provided with a plurality of liquid crystal molecules; the array substrate includes a base substrate; a plurality of data lines and gate lines are formed on the base substrate; the data lines and the gate lines are intersected with and insulated from each other; and one pixel region is defined by two adjacent data lines and two adjacent gate lines intersected with the two adjacent data lines. A pixel electrode and a common electrode are formed in each pixel region, and the common electrode is disposed above the pixel electrode. In related technology, a plurality of elongated slits is formed on each common electrode; and the longitudinal directions of all the elongated slits are in parallel. In the FFS mode display device, the liquid crystal molecules are driven to deflect by the horizontal electric field parallel to an upper surface of the array substrate and formed under the action of the pixel electrodes and the common electrodes through the elongated slits on the common electrodes, so that the light transmittance of the liquid crystal layer can be changed, and hence image display can be achieved.

### SUMMARY

An embodiment of the disclosure provides a display substrate, comprising: a base substrate; first electrodes formed on the base substrate; a first insulating layer formed on the base substrate provided with the first electrodes; and second electrodes formed on the base substrate provided with the first insulating layer, at least one curved slit being formed in each of the second electrodes.

Another embodiment of the disclosure provides a method for manufacturing a display substrate, comprising: forming first electrodes on a base substrate; forming a first insulating layer on the base substrate provided with the first electrodes; and forming second electrodes on the base substrate provided with the first insulating layer, at least one curved slit being formed on the second electrode.

Another embodiment of the disclosure provides a display device comprising: the display substrate as mentioned above.

### BRIEF DESCRIPTION OF THE DRAWINGS

Simple description will be given below to the accompanying drawings of the embodiments to provide a more clear understanding of the technical proposals of the embodiments of the present invention. Obviously, the drawings described below only involve some embodiments of the present invention but are not intended to limit the present invention.

FIG. 1 is a schematic structural view of a display substrate provided by the embodiment of the present invention;

FIG. 2.1 is a schematic structural view of another display substrate provided by the embodiment of the present invention;

FIG. 2.2 is a top view of a display substrate provided by the embodiment as illustrated in FIG. 2.1;

FIG. 2.3 is a top view of another display substrate provided by the embodiment as illustrated in FIG. 2.1;

FIG. 2.4 is a top view of still another display substrate provided by the embodiment as illustrated in FIG. 2.1;

FIG. 2.5 is a schematic diagram illustrating the included angle between slits of the display substrate provided by the embodiment as illustrated in FIG. 2.4;

FIG. 2.6 is a schematic diagram illustrating the deflection of liquid crystals in a display device formed by the display substrate provided by the embodiment as illustrated in FIG. 2.2;

FIG. 3 is a process flowchart of a method for manufacturing a display substrate, provided by the embodiment of the present invention;

FIG. 4.1 is a process flowchart of another method for manufacturing a display substrate, provided by the embodiment of the present invention;

FIG. 4.2 is a top view of the display substrate obtained after the step of forming a plurality of gate lines on a base substrate, in the method provided by the embodiment as illustrated in FIG. 4.1;

FIG. 4.3 is a schematic structural view of the display substrate obtained after the step of forming a second insulating layer on the base substrate provided with the gate lines, in the method provided by the embodiment as illustrated in FIG. 4.1;

FIG. 4.4 is a schematic structural view of the display substrate obtained after the step of forming a plurality of data lines on the base substrate provided with the second insulating layer, in the method provided by the embodiment as illustrated in FIG. 4.1;

FIG. 4.5 is a top view of the display substrate obtained after the step of forming the plurality of data lines on the base substrate provided with the second insulating layer, in the method provided by the embodiment as illustrated in FIG. 4.1;

FIG. 4.6 is a schematic structural view of the display substrate obtained after the step of forming first electrodes on the base substrate provided with the data lines, in the method provided by the embodiment as illustrated in FIG. 4.1;

FIG. 4.7 is a top view of the display substrate obtained after the step of forming the first electrodes on the base substrate provided with the data lines, in the method provided by the embodiment as illustrated in FIG. 4.1;

FIG. 4.8 is a schematic structural view of the display substrate obtained after the step of forming a first insulating layer on the base substrate provided with the first electrodes, in the method provided by the embodiment as illustrated in FIG. 4.1;

FIG. 4.9 is a schematic structural view of the display substrate obtained after the step of forming second electrodes on the base substrate provided with the first insulating layer, in the method provided by the embodiment as illustrated in FIG. 4.1; and

FIG. 4.10 is a top view of the display substrate obtained after the step of forming the second electrodes on the base substrate provided with the first insulating layer, in the method provided by the embodiment as illustrated in FIG. 4.1.

### DETAILED DESCRIPTION

For more clear understanding of the objectives, technical proposals and advantages of the embodiments of the present invention, clear and complete description will be given below to the technical proposals of the embodiments of the present invention with reference to the accompanying drawings of the embodiments of the present invention. Obviously, the preferred embodiments are only partial embodiments of the present invention but not all the embodiments. All the other embodiments obtained by those skilled in the art without creative efforts on the basis of the embodiments of the present invention illustrated shall fall within the scope of protection of the present invention.

As for the FFS mode LCD, the inventor has noticed that the related technology at least has the following problems: as the slits on the common electrodes are elongated slits parallel to each other in the longitudinal direction, the electric fields formed by the elongated slits have single direction and the liquid crystal molecules have single deflection direction, so that light can be emitted from the same direction of the display device, and hence the display device has narrow viewing angle, large difference in the light transmittance in various directions, and large color shift (the colors viewed from different viewing angles are different).

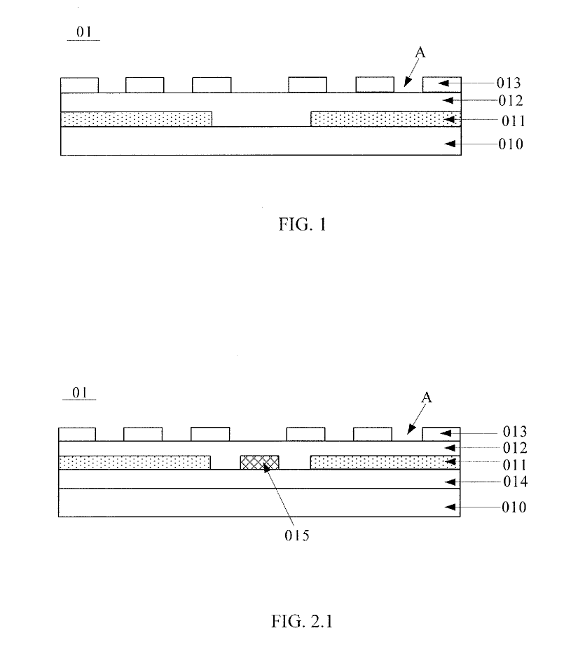

FIG. 1 is a schematic structural view of a display substrate 01 provided by the embodiment of the present invention. As illustrated in FIG. 1, the display substrate 01 may comprise a base substrate 010. The base substrate 010 may be a transparent substrate and may specifically be a substrate made from light guide nonmetallic materials with certain rigidity such as glass, quartz and transparent resin.

First electrodes 011 are formed on the base substrate 010; a first insulating layer 012 is formed on the base substrate 010 provided with the first electrodes 011; second electrodes 013 are formed on the base substrate 010 provided with the first insulating layer 012; and at least one curved slit A is formed in each of the second electrode 013.

In summary, the display substrate provided by the embodiment of the present invention comprises: a base substrate; first electrodes formed on the base substrate; a first insulating layer formed on the base substrate provided with the first electrodes; and second electrodes formed on the base substrate provided with the first insulating layer. At least one curved slit is formed in each of the second electrode. As the slits are curved, the electric fields formed by the first electrodes and the second electrodes are multidirectional, so that light can be emitted from different directions of the display device, and hence the display device has wide viewing angle, small difference in the light transmittance in various directions, and small color shift. Therefore, the problems of narrow viewing angle and large color shift of the display device can be solved, and the effects of widening the viewing angle of the display device and reducing the color shift of the display device can be achieved.

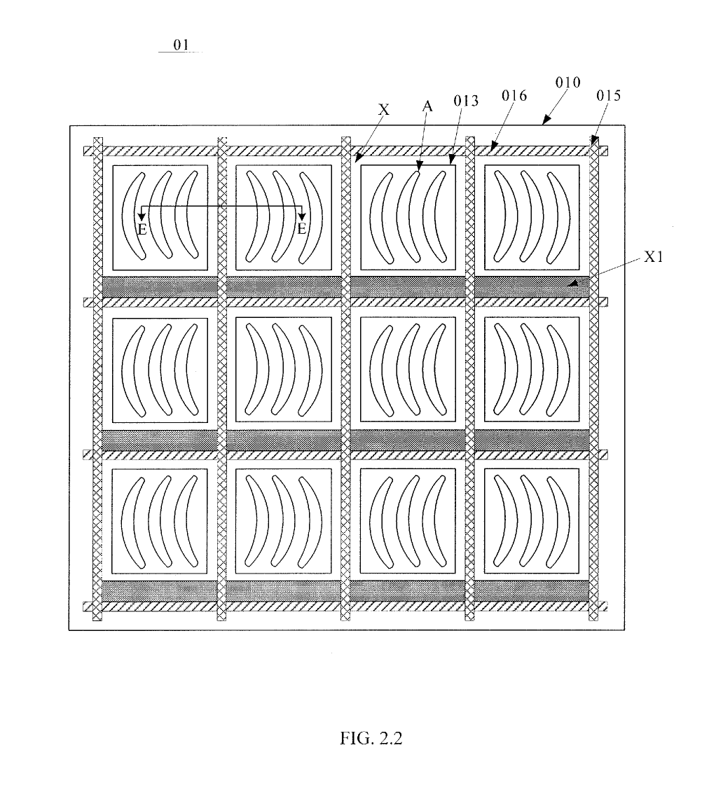

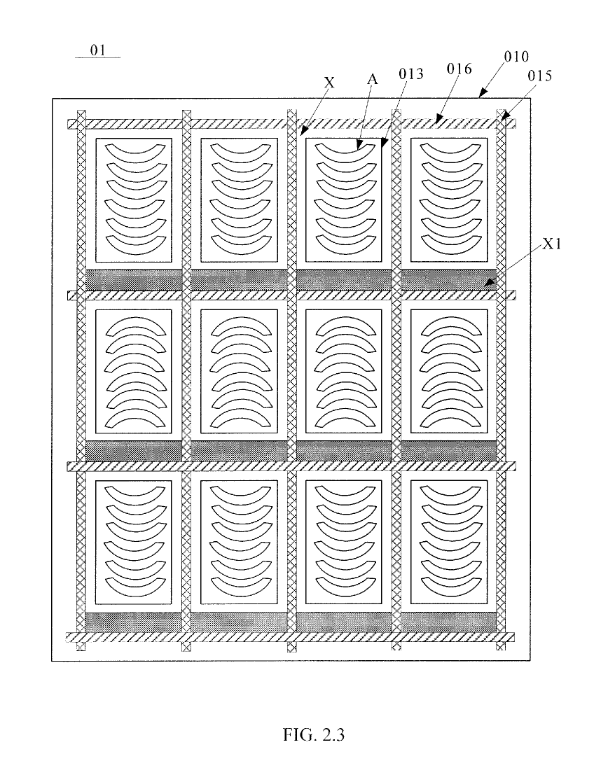

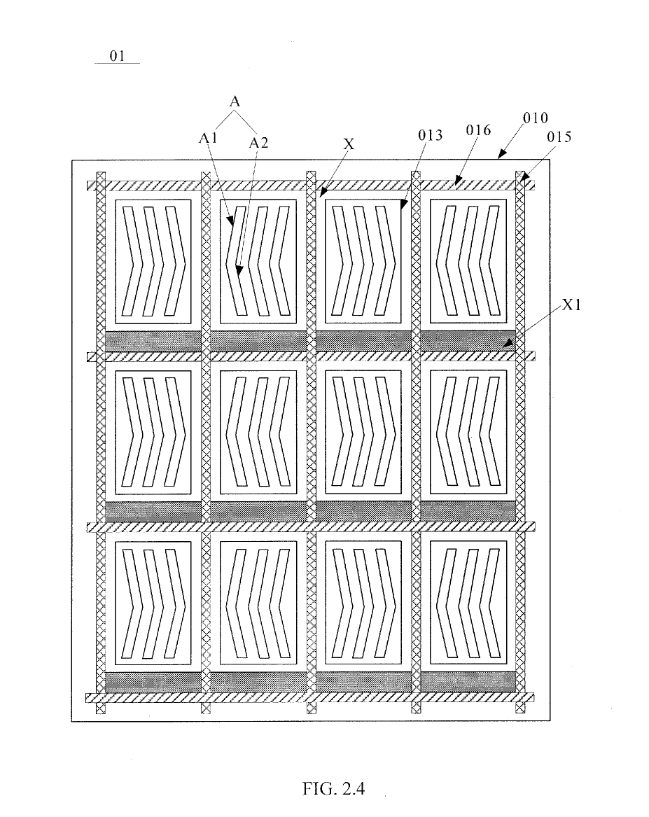

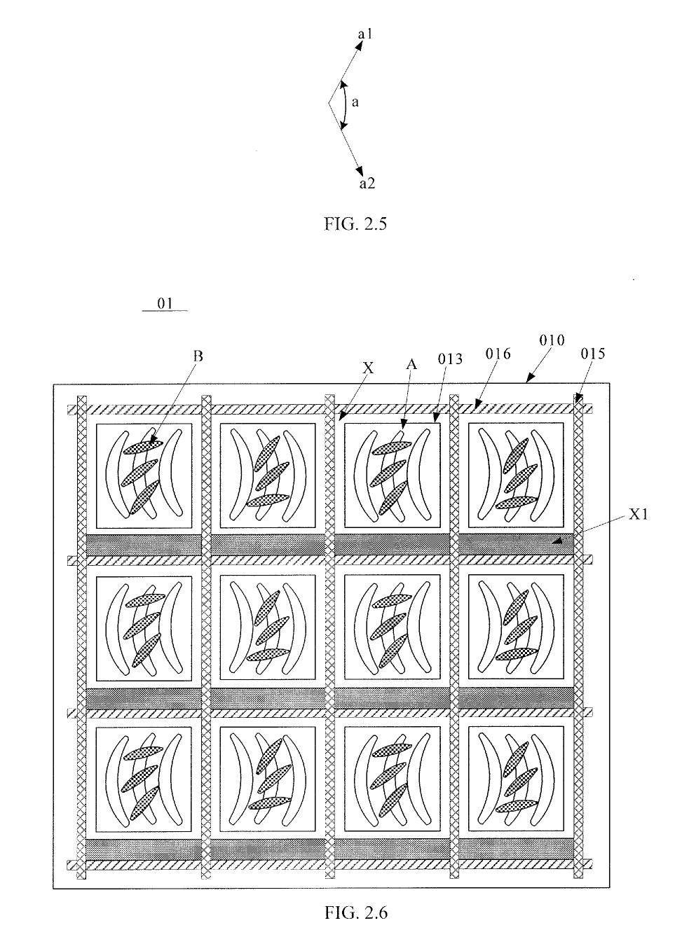

FIG. 2.1 is a schematic structural view of another display substrate 01 provided by the embodiment of the present invention. As illustrated in FIG. 2.1, the display substrate 01 may comprise a base substrate 010. The base substrate 010 may be a transparent substrate and may specifically be a substrate made from light guide nonmetallic materials with certain rigidity such as glass, quartz and transparent resin.

First electrodes 011 are formed on the base substrate 010; a first insulating layer 012 is formed on the base substrate 010 provided with the first electrodes 011; second electrodes 013 are formed on the base substrate 010 provided with the first insulating layer 012; and at least one curved slit A is formed in the second electrode 013. Optionally, in the embodiment of the present invention, the slit A is a semicircular slit; or the slit A is formed by two elongated slits of which one end is communicated, and the included angle between the longitudinal directions of the two elongated slits is ranged from 150 to 178 degrees. As the slit A is set to be the semicircular slit, or the slit A is set to be formed by the two elongated slits of which one end is communicated and the angle between the longitudinal directions of the two elongated slits is ranged from 150 to 178 degrees, the problem that liquid crystals disposed above curved portions of the slits A cannot be deflected due to overlarge degree of curvature can be avoided, and hence liquid crystal dark areas cannot be formed in the display device.

For instance, a plurality of curved slits is formed in each first electrode and the curved slits have a same shape; and the spacing between every two adjacent slits is equal.

Optionally, at least one curved slit (not illustrated in FIG. 2.1) is formed in the first electrode 011.

Moreover, as illustrated in FIG. 2.1, a plurality of gate lines (not illustrated in FIG. 2.1) is formed on the base substrate 010; a second insulating layer 014 is formed on the base substrate 010 provided with the gate lines; a plurality of data lines 015 (only one is illustrated in FIG. 2.1) are formed on the base substrate 010 provided with the second insulating layer 014; the plurality of data lines 015 and the plurality of gate lines are intersected with each other; one pixel region is defined by any two adjacent data lines 015 and any two adjacent gate lines intersected with the two adjacent data lines 015; a plurality of pixel regions are formed on the base substrate 010; a plurality of first electrodes 011 are formed on the base substrate 010 provided with the data lines 015; each first electrode 011 is disposed in one pixel region; a first insulating layer 012 is formed on the base substrate 010 provided with the first electrodes 011; a plurality of second electrodes 013 are formed on the base substrate 010 provided with the first insulating layer 012; at least one curved slit A is formed in each second electrode 013; each second electrode 013 is disposed in one pixel region; any two adjacent second electrodes 013 are symmetrical relative to a signal line disposed between the two adjacent second electrodes 013; the slits on the two adjacent second electrodes 013 are symmetrical relative to the signal line; and the signal line is a gate line or a data line. As the two adjacent second electrodes 013 are symmetrical relative to the signal line disposed between the two adjacent second electrodes 013 and the slits in the two adjacent second electrodes 013 are symmetrical relative to the signal line, electric fields in various directions can be formed by the first electrodes 011 and the second electrodes 013, so that liquid crystal molecules in various directions can all deflect effectively, and hence the viewing angle of the display device can be widened.

Optionally, in the embodiment of the present invention, the first electrode 011 is a pixel electrode, and the second electrode 013 is a common electrode; or the first electrode 011 is a common electrode, and the second electrode 013 is a pixel electrode. No limitation will be given here in the embodiment of the present invention.

Optionally, FIG. 2.2 is a top view of a display substrate 01 provided by the embodiment of the present invention. As illustrated in FIG. 2.2, the display substrate 01 comprises a base substrate 010. A plurality of gate lines 016 (4 gate lines are illustrated in FIG. 2.2) are formed on the base substrate 010 and parallel to each other; a second insulating layer (not illustrated in FIG. 2.2) is formed on the base substrate 010 provided with the gate lines 016; a plurality of data lines 015 (5 data lines are illustrated in FIG. 2.2) are formed on the base substrate 010 provided with the second insulating layer, are parallel to each other, and are perpendicularly intersected with the plurality of gate lines 016; one pixel region X is defined by any two adjacent data lines 015 and any two adjacent gate lines 016 intersected with the two adjacent data lines 015, and a plurality of pixel regions X are formed on the base substrate 010; a plurality of first electrodes (not illustrated in FIG. 2.2) are formed on the base substrate 010 provided with the data lines 015; each first electrode is disposed in one pixel region X; a first insulating layer (not illustrated in FIG. 2.2) is formed on the base substrate 010 provided with the first electrodes; a plurality of second electrodes 013 are formed on the base substrate 010 provided with the first insulating layer; at least one curved slit A is formed in each second electrode 013; each second electrode 013 is disposed in one pixel region X; any two adjacent second electrodes 013 are symmetrical relative to a signal line disposed between the two adjacent second electrodes 013; the slits A in the two adjacent second electrodes 013 are symmetrical relative to the signal line disposed between the two adjacent second electrodes 013; and the signal line is a gate line or a data line. Optionally, as illustrated in FIG. 2.2, 3 slits A are formed in each second electrode 013; each slit A is a semicircular slit; and openings of 3 slits A in any second electrode 013 have same orientation and are all towards the data line 015.

Optionally, FIG. 2.3 is a top view of another display substrate 01 provided by the embodiment of the present invention. As illustrated in FIG. 2.3, 6 slits A are formed in each second electrode 013; each second electrode 013 is disposed in one pixel region X; any two adjacent second electrodes 013 are symmetrical relative to a signal line disposed between the two adjacent second electrodes 013; the slits A in the two adjacent second electrodes 013 are symmetrical relative to the signal line disposed between the two adjacent second electrodes 013; and the signal line is a gate line or a data line. Each slit A is a semicircular slit, and openings of 6 slits A in any second electrode 013 have a same orientation and are all towards the gate line 016.

It should be noted that: in the embodiment of the present invention, the semicircular slit may be haft of a circular slit or half of an elliptical slit and may also be one portion intercepted from the circular slit or the elliptical slit. The schematic structural view of the display substrate 01 as illustrated in FIG. 2.1 may be seen as the sectional view of an E-E portion of the display substrate 01 as illustrated in FIG. 2.2. No limitation will be given here in the embodiment of the present invention.

Optionally, FIG. 2.4 is a top view of still another display substrate 01 provided by the embodiment of the present invention. As illustrated in FIG. 2.4, 3 slits A are formed in each second electrode 013, and each second electrode 013 is disposed in one pixel region X; any two, adjacent second electrodes 013 are symmetrical relative to a signal line disposed between the two adjacent second electrodes 013, and the slits A in the two adjacent second electrodes 013 are symmetrical relative to the signal line disposed between the two adjacent two second electrodes 013; and the signal line is a gate line or a data line. Each slit A is formed by two elongated slits of which one end is communicated. As illustrated in FIG. 2.4, the two elongated slits include an elongated slit A1 and an elongated slit A2. The longitudinal direction of the elongated slit A1 is a1 (not marked in FIG. 2.4), and the longitudinal direction of the elongated slit A2 is a2 (not marked in FIG. 2.4). FIG. 2.5 is a schematic diagram illustrating the included angle between the slits A of the display substrate 01 provided by the embodiment as illustrated in FIG. 2.4. As illustrated in FIG. 2.5, the angle between the longitudinal direction al of the elongated slit and the longitudinal direction a2 of the elongated slit is a. The angle a may be ranged from 150 to 178 degrees. No limitation will be given here in the embodiment of the present invention.

FIG. 2.6 is a schematic diagram illustrating the deflection of liquid crystals in a display device formed by the display substrate 01 provided by the embodiment as illustrated in FIG. 2.2. As illustrated in FIG. 2.6, the deflection directions of adjacent liquid crystal molecules B are different. Thus, the viewing angle of the display device can be widened and the problem of color shift of the display device can be improved.

It should be noted that in the embodiment of the present invention, the specific number of the slits A in each second electrode 013 may be set according to actual conditions. No limitation will be given here in the embodiment of the present invention. Moreover, as illustrated in FIGS. 2.2 to 2.4 and FIG. 2.6, each pixel region X further includes a device placing area X1. The device placing area X1 is used for placing a driving element which may be a thin-film transistor (TFT). The TFT may include a gate electrode, a source electrode and a drain electrode. The gate electrode may be connected with a gate line 016; the source electrode may be connected with a data line 015; and the drain electrode may be connected with a pixel electrode. For instance, the gate electrodes and the gate lines 016 may be formed by the same patterning process, and the source electrodes, the drain electrodes and the data lines 015 may be formed by the same patterning process. No limitation will be given here in the embodiment of the present invention.

In summary, the display substrate provided by the embodiment of the present invention comprises: a base substrate; first electrodes formed on the base substrate; a first insulating layer formed on the base substrate provided with the first electrodes; and second electrodes formed on the base substrate provided with the first insulating layer. At least one curved slit is formed in the second electrode. As the slits are curved, the electric fields formed by the first electrodes and the second electrodes are multidirectional, so that light can be emitted from different directions of the display device, and hence the display device has wide viewing angle, small different in the light transmittance in various directions, and small color shift. Therefore, the problems of narrow viewing angle of the display device and large color shift of the display device can be solved, and the effects of widening the viewing angle of the display device and reducing the color shift of the display device can be achieved.

The display substrate provided by the embodiment of the present invention can maintain the aperture opening ratio of the traditional display substrate and is easy to produce. Moreover, the two adjacent second electrodes are symmetrical relative to the signal line disposed between the two adjacent second electrodes; the slits on the two adjacent second electrodes are symmetrical relative to the signal line disposed between the two adjacent second electrodes; and the signal line is the gate line or the data line. Therefore, liquid crystal molecules above the two adjacent second electrodes can rotate towards different directions, so that the viewing angle of the display device can be widened and the problem of color shift of the display device can be improved, and hence the display quality of the display device can be improved.

The display substrate provided by the embodiment of the present invention effectively solves the problems of narrow viewing angle and large color shift of the display device by improving the shape of the slits on the second electrodes and combining the multi-quadrant configuration of the second electrodes and the symmetrical design of adjacent second electrodes.

It should be noted that the display substrate provided by the embodiment of the present invention is applicable to the production of FFS mode display devices. In an FFS mode display device, common electrodes and pixel electrodes are arranged on the same substrate which may be an array substrate or a CF substrate, which is not limited in the embodiment of the present invention. For instance, the display substrate provided by the embodiment of the present invention is an array substrate of an LCD device.

The display substrate provided by the embodiment of the present invention may be applied to the following method. The manufacturing method and the manufacturing principles of the display substrate provided by the embodiment of the present invention may refer to the description on the following embodiments.

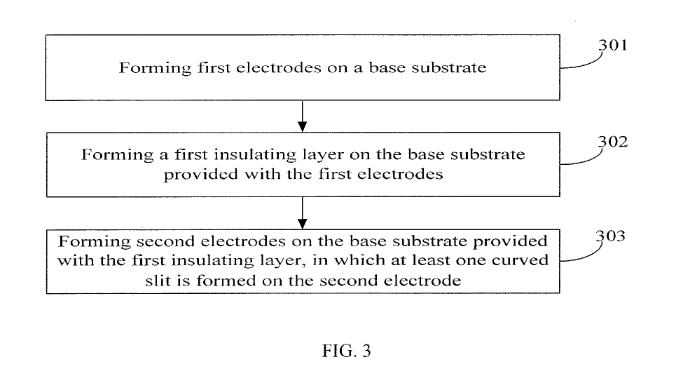

FIG. 3 is a process flowchart of a method for manufacturing a display substrate, provided by the embodiment of the present invention. The method for manufacturing the display substrate may be used for manufacturing the display substrate 01 as illustrated in any one of FIGS. 1 to 2.4. The display substrate 01 may comprise: a base substrate 010. The base substrate 010 may be a transparent substrate and may specifically be a substrate made from light guide nonmetallic materials with certain rigidity such as glass, quartz and transparent resin. As illustrated in FIG. 3, the method for manufacturing the display substrate may comprise the following steps:

S301: forming first electrodes on a base substrate;

S302: forming a first insulating layer on the base substrate provided with the first electrodes; and

S303: forming second electrodes on the base substrate provided with the first insulating layer, in which at least one curved slit is formed in each of the second electrodes.

In summary, in the method for manufacturing the display substrate, provided by the embodiment of the present invention, the first electrodes are formed on the base substrate; the first insulating layer is formed on the base substrate provided with the first electrodes; the second electrodes are formed on the base substrate provided with the first insulating layer; and at least one curved slit is formed on the second electrode. As the slits are curved, the electric fields formed by the first electrodes and the second electrodes are multidirectional, so that light can be emitted from different directions of the display device, and hence the display device has wide viewing angle, small difference in the light transmittance in various directions, and small color shift. Therefore, the problems of narrow viewing angle and large color shift of the display device can be solved, and the effects of widening the viewing angle of the display device and reducing the color shift of the display device can be achieved.

Optionally, the step S301 may include: forming the first electrodes on the base substrate, and forming at least one curved slit on the first electrode.

Optionally, the step S301 may include:

forming a plurality of gate lines on the base substrate;

forming a second insulating layer on the base substrate provided with the gate lines;

forming a plurality of data lines on the base substrate provided with the second insulating layer, in which the plurality of data lines are intersected with the plurality of gate lines; one pixel region is defined by any two adjacent data lines and any two adjacent gate lines intersected with the two adjacent data lines; a plurality of pixel regions are formed on the base substrate; and

forming a plurality of first electrodes on the base substrate provided with the data lines, in which each first electrode is disposed in one pixel region.

The step S303 may include:

forming a plurality of second electrodes on the base substrate provided with the first insulating layer, in which at least one curved slit is formed in each second electrode, and each second electrode is disposed in one pixel region; any two adjacent second electrodes are symmetrical relative to a signal line disposed between the two adjacent second electrodes; the slits on the two adjacent second electrodes are symmetrical relative to the signal line; and the signal line is a gate line or a data line.

Optionally, the slit is a semicircular slit; or

the slit is formed by two elongated slits of which one end is communicated, and the angle between the longitudinal directions of the two elongated slits is ranged from 150 to 178 degrees.

Optionally, the first electrode is a pixel electrode, and the second electrode is a common electrode; or

the first electrode is a common electrode, and the second electrode is a pixel electrode.

All the optional technical proposals may be randomly combined to form the preferred embodiments of the present invention. No further description will be given here.

In summary, in the method for manufacturing the display substrate, provided by the embodiment of the present invention, the first electrodes are formed on the base substrate; the first insulating layer is formed on the base substrate provided with the first electrodes; the second electrodes are formed on the base substrate provided with the first insulating layer; and at least one curved slit is formed on the second electrode. As the slits are curved, the electric fields formed by the first electrodes and the second electrodes are multidirectional, so that light can be emitted from different directions of the display device, and hence the display device has wide viewing angle, small difference in the light transmittance in various directions, and small color shift. Therefore, the problems of narrow viewing angle and large color shift of the display device can be solved, and the effects of widening the viewing angle of the display device and reducing the color shift of the display device can be achieved.

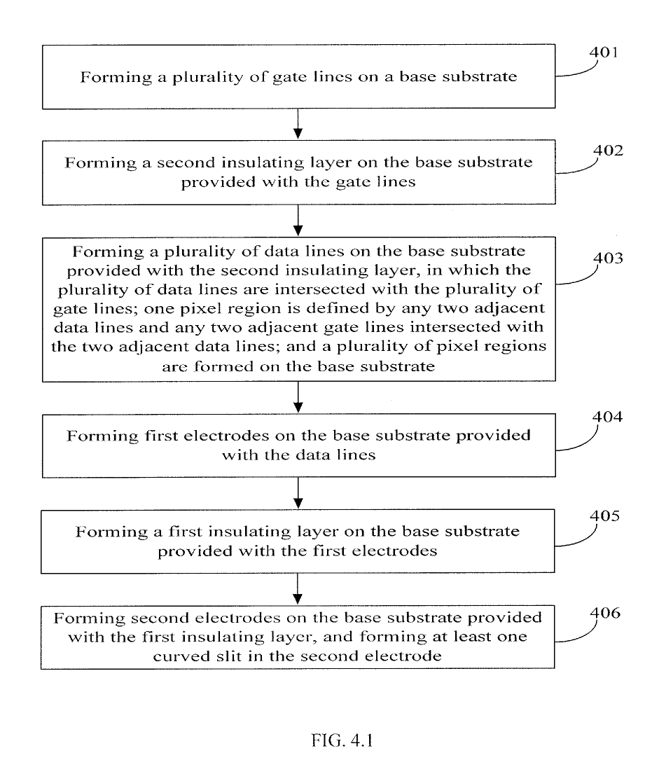

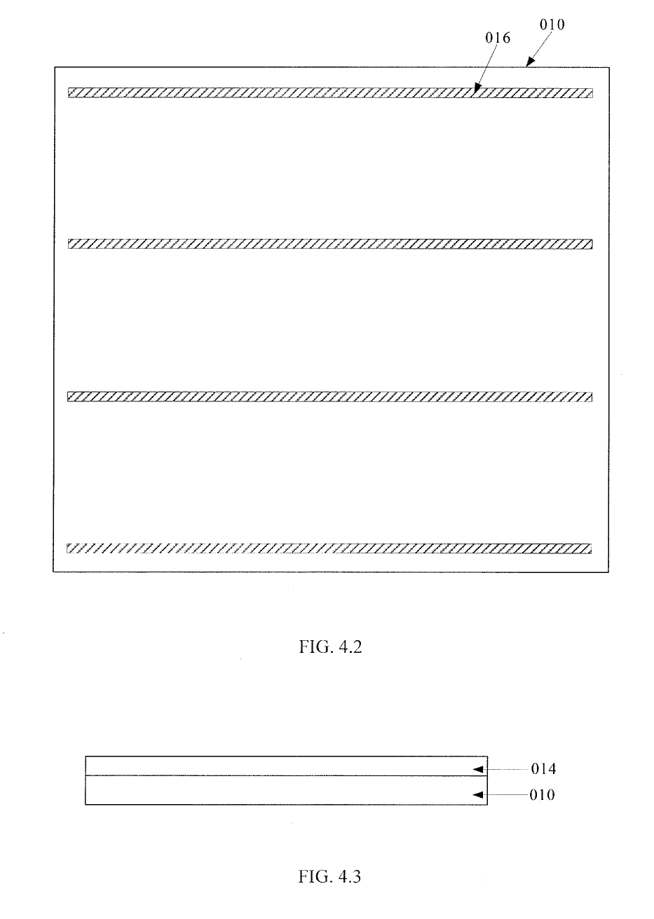

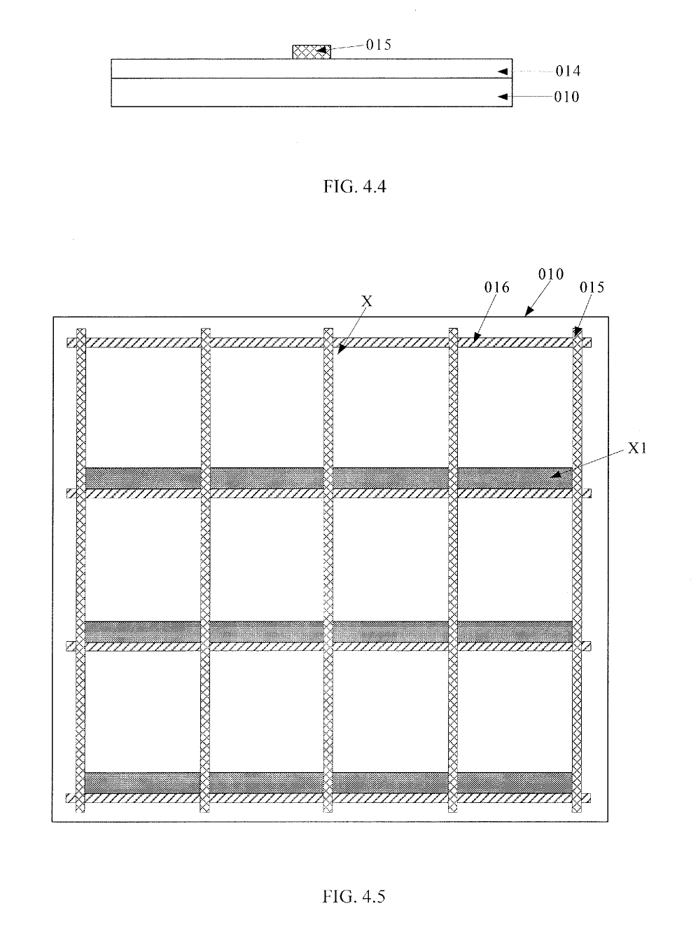

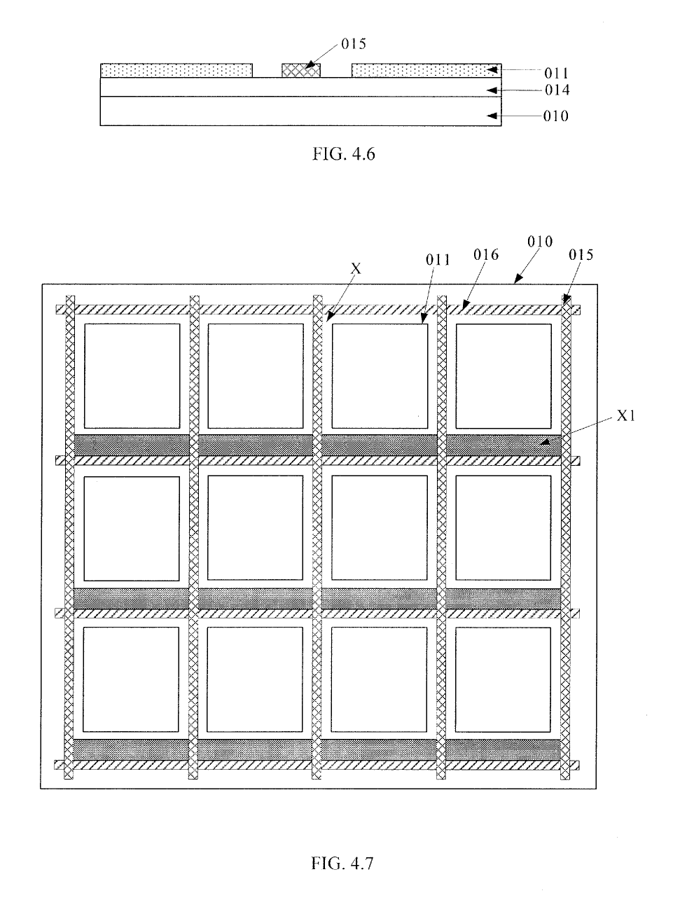

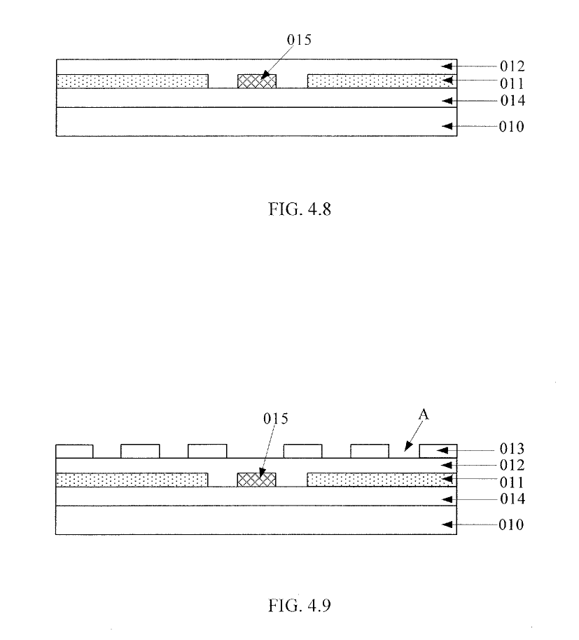

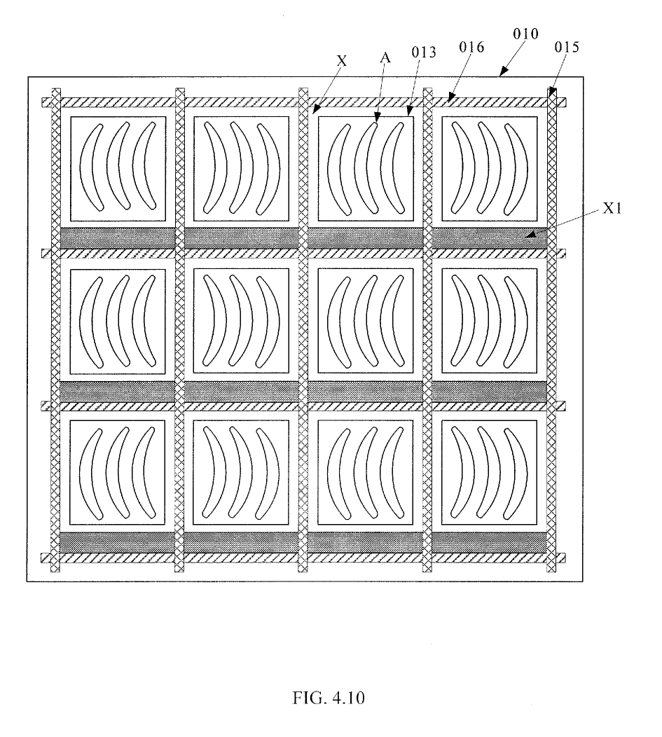

FIG. 4.1 is a process flowchart of another method for manufacturing a display substrate, provided by the embodiment of the present invention. The method for manufacturing the display substrate may be used for manufacturing the display substrate 01 as illustrated in any one of FIGS. 1 to 2.4. The display substrate 01 may comprise: a base substrate 010. The base substrate 010 may be a transparent substrate and may specifically be a substrate made from light guide nonmetallic materials with certain rigidity such as glass, quartz and transparent resin. As illustrated in FIG. 4.1, the method for manufacturing the display substrate may comprise the following steps:

S401: forming a plurality of gate lines on a base substrate.

FIG. 4.2 is a top view of the display substrate obtained after the step of forming a plurality of gate lines 016 on the base substrate 010, in the method provided by the embodiment as illustrated in FIG. 4.1. As illustrated in FIG. 4.2, the gate lines 016 are parallel to each other.

The gate lines 016 may be made from metallic materials. Illustratively, one layer of metallic materials may be deposited on the base substrate 010 to form a metal layer by coating, magnetron sputtering, thermal evaporation, plasma enhanced chemical vapor deposition (PECVD) and other processes, and subsequently, the plurality of gate lines 016 are obtained after processing the metal layer by one patterning process. Wherein, one patterning process includes: photoresist coating, exposure, development, etching and photoresist stripping. Thus, the step of obtaining the plurality of gate lines 016 after processing the metal layer by one patterning process may include: firstly, one layer of photoresist with certain thickness is coated on the metal layer; secondly, the photoresist is subjected to exposure via a mask, so that full exposure areas and non-exposure areas are formed by the photoresist; thirdly, the development process is adopted for treatment, so that the photoresist at the full exposure areas is completely removed and the photoresist at the non-exposure areas is completely retained; fourthly, areas on the metal layer corresponding to the full exposure areas are etched by etching process; and finally, the photoresist at the non-exposure areas is stripped off, and the gate lines 016 are formed at areas on the metal layer corresponding to the non-exposure areas.

It should be noted that description is given in the embodiment of the present invention by taking the case that the gate lines 016 are formed by positive photoresist as an example. In actual application, the gate lines 016 may also be formed by negative photoresist. No limitation will be given here in the embodiment of the present invention.

It should be also noted that: in actual application, the display substrate further comprises TFTs; the TFT includes a gate electrode, a source electrode and a drain electrode; the gate electrodes are connected with the gate lines 016. Thus, when the gate lines 016 are formed, the gate electrodes of the TFTs may also be formed on the base substrate 010. That is to say, the gate electrodes and the gate lines 016 are formed by the same patterning process. No limitation will be given here in the embodiment of the present invention.

S402: forming a second insulating layer on the base substrate provided with the gate lines.

FIG. 4.3 is a schematic structural view of the display substrate obtained after the step of forming a second insulating layer 014 on the base substrate 010 provided with the gate lines, in the method provided by the embodiment as illustrated in FIG. 4.1. Wherein, the gate lines are not illustrated in FIG. 4.3. The second insulating layer 014 may be made from organic resin materials, and the thickness of the second insulating layer 014 may be set according to actual demands. No limitation will be given here in the embodiment of the present invention.

Illustratively, one organic resin film with certain thickness may be deposited on the base substrate 010 provided with the gate lines to form the second insulating layer 014 by coating, magnetron sputtering, thermal evaporation, PECVD and other processes. Wherein, the second insulating layer 014 may be formed by oxide, nitride or oxynitride, and corresponding reaction gas may be mixed gas of SiH₄ (silicon tetrahydride), NH₃ (ammonia), N₂ (nitrogen) or mixed gas of SiH₂Cl₂ (dichlorosilane), NH₃ and N₂. As the second insulating layer 014 is formed on the base substrate provided with the gate lines, the gate lines and subsequent data lines may be insulated from each other.

It should be noted that: in actual application, when the second insulating layer 014 includes a pattern, the second insulating layer 014 may also be obtained after processing the organic resin film by patterning process. No limitation will be given here in the embodiment of the present invention.

S403: forming a plurality of data lines on the base substrate provided with the second insulating layer, in which the plurality of data lines are intersected with the plurality of gate lines; one pixel region is defined by any two adjacent data lines and any two adjacent gate lines intersected with the two adjacent data lines; and a plurality of pixel regions are formed on the base substrate.

FIG. 4.4 is a schematic structural view of the base substrate obtained after the step of forming a plurality of data lines 015 on the base substrate 010 provided with the second insulating layer 014, provided by the embodiment as illustrated in FIG. 4.1. As illustrated in FIG. 4.4, the data lines 015 are disposed on the second insulating layer 014. Thus, the data lines 015 and the gate lines are insulated from each other.

FIG. 4.5 is a top view of the base substrate obtained after the step of forming the plurality of data lines 015 on the base substrate 010 provided with the second insulating layer 014, in the method provided by the embodiment as illustrated in FIG. 4.1. As illustrated in FIG. 4.5, the plurality of data lines 015 are parallel to each other; each data line 015 is perpendicularly intersected with all the gate lines 016; one pixel region X is defined by any two adjacent data lines 015 and any two adjacent gate lines 016 intersected with the two adjacent data lines 015; and a plurality of pixel regions X are formed on the base substrate 010. As illustrated in FIG. 4.5, each pixel region X includes a device placing area X1 which is used for placing a driving element (not illustrated in FIG. 4.5). The driving element may be a TFT, which is not limited in the embodiment of the present invention.

The forming process of the plurality of data lines 015 may refer to the forming process of the plurality of gate lines 016 in the step S401. No further description will be given here in the embodiment of the present invention. But it should be noted that: as the source electrodes of the TFTs of the display substrate are connected with the data lines and the source electrodes and the drain electrodes of the TFTs are arranged in the same layer, when the data lines 015 are formed, the source electrodes and the drain electrodes of the TFTs may also be formed on the base substrate 010 provided with the second insulating layer 014, namely the source electrodes, the drain electrodes and the data lines 015 are formed by the same pattering process. No limitation will be give here in the embodiment of the present invention.

S404: forming first electrodes on the base substrate provided with the data lines.

FIG. 4.6 is a schematic structural view of the base substrate obtained after the step of forming first electrodes 011 on the base substrate 010 provided with the data lines 015, in the method provided by the embodiment as illustrated in FIG. 4.1. As illustrated in FIG. 4.6, the first electrodes 011 and the data lines 015 are arranged in the same layer. FIG. 4.7 is a top view of the base substrate obtained after the step of forming the first electrodes 011 on the base substrate 010 provided with the data lines 015, in the method provided by the embodiment as illustrated in FIG. 4.1. As illustrated in FIG. 4.7, one first electrode 011 is formed in each pixel region X. Thus, the step of forming the first electrodes 011 on the base substrate 010 provided with the data lines 015 is also the step of forming a plurality of first electrodes 011 on the base substrate 010 provided with the data lines 015 and allowing each first electrode 011 to be disposed in one pixel region X. Wherein, the first electrode 011 may be a pixel electrode or a common electrode, which is not limited in the embodiment of the present invention. Description is given in the embodiment of the present invention by taking the case that the first electrode 011 is a pixel electrode as an example.

The first electrodes 011 may be made from metallic materials. Illustratively, one layer of metallic materials may be deposited on the base substrate 010 provided with the data lines 015 to form a metal layer by coating, magnetron sputtering, thermal evaporation, PECVD and other processes, and subsequently, the first electrodes 011 are obtained after processing the metal layer by one patterning process. Wherein, one patterning process includes: photoresist coating, exposure, development, etching and photoresist stripping. Thus, the step of obtaining the first electrodes 011 after processing the metal layer by one patterning process may include: firstly, one layer of photoresist with certain thickness is coated on the metal layer; secondly, the photoresist is subjected to exposure via a mask, so that full exposure areas and non-exposure areas are formed by the photoresist; thirdly, the development process is adopted for treatment, so that the photoresist at the full exposure areas is completely removed and the photoresist at the non-exposure areas is completely retained; fourthly, areas on the metal layer corresponding to the full exposure areas are etched by etching process; and finally, the photoresist at the non-exposure areas is stripped off, and the first electrodes 011 are formed at areas on the metal layer corresponding to the non-exposure areas.

It should be noted that description is given in the embodiment of the present invention by taking the case that the first electrodes 011 are formed by positive photoresist as an example. In actual application, the first electrodes 011 may also be formed by negative photoresist, which is not limited in the embodiment of the present invention.

It should be also noted that description is given in the embodiment of the present invention by taking the case that no slit is formed on the first electrode 011 as an example. In actual application, slits may also be formed in the first electrode 011. Moreover, the slit may be a semicircular slit; or the slit may be formed by two elongated slits of which one end is communicated. When the slit is formed by the two elongated slits of which one end is communicated, the angle between the longitudinal directions of the two elongated slits is ranged from 150 to 178 degrees. Thus, liquid crystal dark areas of the display device can be avoided. In the case of forming the slits on the first electrodes 011, when the first electrodes 011 are formed, corresponding mask is required to perform exposure on photoresist, and subsequently development, etching and stripping processes are adopted for treatment. No further description will be given here in the embodiment of the present invention.

S405: forming a first insulating layer on the base substrate provided with the first electrodes.

FIG. 4.8 is a schematic structural view of the base substrate obtained after the step of forming a first insulating layer 012 on the base substrate 010 provided with the first electrodes 011, in the method provided by the embodiment as illustrated in FIG. 4.1. Wherein, as the first insulating layer 012 is formed on the base substrate 010 provided with the first electrodes 011, the first electrodes 011 and the data lines 015 may be insulated from subsequently formed second electrodes. The specific forming process of the first insulating layer 012 may refer to the step S402. No further description will be given here in the embodiment of the present invention.

S406: forming second electrodes on the base substrate provided with the first insulating layer, and forming at least one curved slit in the second electrode.

FIG. 4.9 is a schematic structural view of the base substrate obtained after the step of forming second electrodes 013 on the base substrate 010 provided with the first insulating layer 012, in the method provided by the embodiment as illustrated in FIG. 4.1. As illustrated in FIG. 4.9, at least one slit A is formed in the second electrode 013. FIG. 4.10 is a top view of the base substrate obtained after the step of forming the second electrodes 013 on the base substrate 010 provided with the first insulating layer 012, in the method provided by the embodiment as illustrated in FIG. 4.1. As illustrated in FIG. 4.10, one second electrode 013 is formed in each pixel region X, and at least one curved slit A is formed in each second electrode 013; any two adjacent second electrodes 013 are symmetrical relative to a signal line disposed between the two adjacent second electrodes 013, and the slits A on the two adjacent second electrodes 013 are symmetrical relative to the signal line disposed between the two adjacent second electrodes 013; and the signal line is a gate line or a data line. Illustratively, as illustrated in FIG. 4.10, the slit A may be a semicircular slit.

In the embodiment of the present invention, the step of forming the second electrodes 013 on the base substrate 010 provided with the first insulating layer 012 and forming at least one curved slit A on the second electrode 013 may include: forming a plurality of second electrodes 013 on the base substrate 010 provided with the first insulating layer 012, in which at least one curved slit A is formed on each second electrode 013, and each second electrode 013 is disposed in one pixel region; the two adjacent second electrodes 013 are symmetrical relative to the signal line disposed between the two adjacent second electrodes 013, and the slits A on the two adjacent second electrodes 013 are symmetrical relative to the signal line disposed between the two adjacent second electrodes 013; and the signal line is a gate line or a data line. Wherein, the second electrode 013 may be a pixel electrode or a common electrode, which is not limited in the embodiment of the present invention. Description is given in the embodiment of the present invention by taking the case that the second electrode 013 is a common electrode as an example.

In the embodiment of the present invention, the second electrodes 013 may be made from metallic materials. Illustratively, one layer of metallic materials may be deposited on the base substrate 010 provided with the first insulating layer 012 to form a metal layer by coating, magnetron sputtering, thermal evaporation, PECVD and other processes, and subsequently, the second electrodes 013 are obtained after processing the metal layer by one patterning process. Wherein, one patterning process includes: photoresist coating, exposure, development, etching and photoresist stripping. Thus, the step of obtaining the second electrodes 013 after processing the metal layer by one patterning process may include: firstly, one layer of photoresist with certain thickness is coated on the metal layer; secondly, the photoresist is subjected to exposure via a mask with a specific pattern, so that full exposure areas and non-exposure areas are formed by the photoresist; thirdly, the development process is adopted for treatment, so that the photoresist at the full exposure areas is completely removed and the photoresist at the non-exposure areas is completely retained; fourthly, areas on the metal layer corresponding to the full exposure areas are etched by etching process; and finally, the photoresist at the non-exposure areas is stripped off, and the second electrodes 013 are formed at areas on the metal layer corresponding to the non-exposure areas. Wherein, the full exposure areas may be areas on the photoresist corresponding to the slits A. No limitation will be given here in the embodiment of the present invention.

It should be noted that description is given in the embodiment of the present invention by taking the case that the second electrodes 013 are formed by positive photoresist as an example. In actual application, the second electrodes 013 may also be formed by negative photoresist, which is not limited in the embodiment of the present invention.

It should be noted that the above description is given by taken the case that the first electrodes and the second electrodes are made of metal materials as an example. However, the embodiments of the disclosure are not limited thereto. The first electrodes and the second electrodes can also be made of other conductive materials, for example, transparent metal oxide material.

It should be noted that description is given in the embodiment of the present invention by taking the case that no slit is formed in the first electrode 011 and the slits are formed in the second electrode 013 as an example. The method for manufacturing the display substrate, in which the slits are formed in the first electrode 011 and no slit is formed on the second electrode 013, or the slits are formed in both the first electrode 011 and the second electrode 013, may refer to the method for manufacturing the display substrate as illustrated in FIG. 4.1. No further description will be given here in the embodiment of the present invention. But it should be noted that: when the slits are formed in both the first electrode 011 and the second electrode 013, in order to form the electric fields parallel to the base substrate 010 under the action of the first electrodes 011 and the second electrodes 013, projections of the first electrode 011 and the second electrode 013 in the same pixel region X on the base substrate 010 are not superimposed.

In summary, in the method for manufacturing the display substrate, provided by the embodiment of the present invention, the first electrodes are formed on the base substrate; the first insulating layer is formed on the base substrate provided with the first electrodes; the second electrodes are formed on the base substrate provided with the first insulating layer; and at least one curved slit is formed on the second electrode. As the slits are curved, the electric fields formed by the first electrodes and the second electrodes are multidirectional, so that light can be emitted from different directions of the display device, and hence the display device has wide viewing angle, small difference in the light transmittance in various directions, and small color shift. Therefore, the problems of narrow viewing angle and large color shift of the display device can be solved, and the effects of widening the viewing angle of the display device and reducing the color shift of the display device can be achieved.

The method for manufacturing the display substrate, provided by the embodiment of the present invention, can maintain the aperture opening ratio of the traditional display substrate and is easy to produce. Moreover, the two adjacent second electrodes are symmetrical relative to the signal line disposed between the two adjacent second electrodes; the slits on the two adjacent second electrodes are symmetrical relative to the signal line disposed between the two adjacent second electrodes; and the signal line is the gate line or the data line. Therefore, liquid crystal molecules above the two adjacent second electrodes can rotate towards different directions, so that the viewing angle of the display device can be widened and the problem of color shift of the display device can be improved, and hence the display quality of the display device can be improved.

The method for manufacturing the display substrate, provided by the embodiment of the present invention, effectively solves the problems of narrow viewing angle and large color shift of the display device by improving the shape of the slits on the second electrodes and combining the multi-quadrant configuration of the second electrodes and the symmetrical design of adjacent second electrodes.

The embodiment of the present invention further provides a display device, which may comprise the display substrate 01 as illustrated in any one of FIGS. 1 to 2.4. Illustratively, the display device may be: any product or component with display function such as an LCD panel, c-paper, a mobile phone, a tablet PC, a TV, a display, a notebook computer, a photographic camera, a video camera, a digital picture frame and a navigator.

Detailed description has been given to the structure of the display substrate 01 in the foregoing embodiments. No further description will be given here in the embodiment of the present invention.

In summary, the display device provided by the embodiment of the present invention comprises the display substrate; the first electrodes are formed on the base substrate of the display substrate; the first insulating layer is formed on the base substrate provided with the first electrodes; the second electrodes are formed on the base substrate provided with the first insulating layer; and at least one curved slit is formed on the second electrode. As the slits are curved, the electric fields formed by the first electrodes and the second electrodes are multidirectional, so that light can be emitted from different directions of the display device, and hence the display device has wide viewing angle, small difference in the light transmittance in various directions, and small color shift. Therefore, the problems of narrow viewing angle and large color shift of the display device can be solved, and the effects of widening the viewing angle of the display device and reducing the color shift of the display device can be achieved.

The display device provided by the embodiment of the present invention can maintain the aperture opening ratio of the traditional display substrate and is easy to produce. Moreover, the two adjacent second electrodes are symmetrical relative to the signal line disposed between the two adjacent second electrodes; the slits on the two adjacent second electrodes are symmetrical relative to the signal line disposed between the two adjacent second electrodes; and the signal line is the gate line or the data line. Therefore, liquid crystal molecules above the two adjacent second electrodes can rotate towards different directions, so that the viewing angle of the display device can be widened and the problem of color shift of the display device can be improved, and hence the display quality of the display device can be improved.

The display device provided by the embodiment of the present invention effectively solves the problems of narrow viewing angle and large color shift of the display device by improving the shape of the slits on the second electrodes and combining the multi-quadrant configuration of the second electrodes and the symmetrical design of adjacent second electrodes.

It should be understood by those skilled in the art that all or partial steps for implementing the embodiments may be finished by hardware and may also be finished by the instruction of relevant hardware via programs. The programs may be stored in a computer-readable storage medium. The storage medium may be a read-only memory, a magnetic disc, a compact disc (CD), etc.

The foregoing is only the preferred embodiments of the present invention and not intended to limit the scope of protection of the present invention. The scope of protection of the present invention should be defined by the appended claims.

The application claims priority to the Chinese patent application No. 201610031519.5, filed Jan. 18, 2016, the disclosure of which is incorporated herein by reference as part of the application.

1. A display substrate, comprising:
a base substrate;
first electrodes formed on the base substrate;
a first insulating layer formed on the base substrate provided with the first electrodes; and
second electrodes formed on the base substrate provided with the first insulating layer, at least one curved slit being formed in each of the second electrodes.

2. The display substrate according to claim 1, wherein
at least one curved slit is formed in each of the first electrodes.

3. The display substrate according to claim 1, wherein
a plurality of gate lines is formed on the base substrate;
a second insulating layer is formed on the base substrate provided with the gate lines;
a plurality of data lines is formed on the base substrate provided with the second insulating layer, the plurality of data lines is intersected with the plurality of gate lines; one pixel region is defined by any two adjacent data lines and any two adjacent gate lines intersected with the two adjacent data lines; a plurality of pixel regions is formed on the base substrate;
the first electrodes are formed on the base substrate provided with the data lines, each first electrode is disposed in one pixel region;
the first insulating layer is formed on the base substrate provided with the first electrodes; and
the second electrodes are formed on the base substrate provided with the first insulating layer, at least one curved slit is formed in each second electrode; each second electrode is disposed in one pixel region; and any two adjacent second electrodes are symmetrical relative to one of the gate lines or one of the data lines disposed between the two adjacent second electrodes.

4. The display substrate according to claim 1, wherein
the slit is a semicircular slit; or
the slit is formed by two elongated slits of which one end is communicated, and an angle between the longitudinal directions of the two elongated slits is ranged from 150 to 178 degrees.

5. The display substrate according to claim 1, wherein
each of the first electrodes is a pixel electrode, and each of the second electrodes is a common electrode; or
each of the first electrodes is a common electrode, and each of the second electrodes is a pixel electrode.

6. The display substrate according to claim 3, wherein
a plurality of curved slits is formed in each first electrode and the curved slits have a same shape; and an interval between every two adjacent slits is equal.

7. The display substrate according to claim 1, wherein
the display substrate is an array substrate of a liquid crystal display (LCD) device.

8. A method for manufacturing a display substrate, comprising:
forming first electrodes on a base substrate;
forming a first insulating layer on the base substrate provided with the first electrodes; and
forming second electrodes on the base substrate provided with the first insulating layer, at least one curved slit being formed on the second electrode.

9. The method according to claim 8, wherein
forming the first electrodes on the base substrate includes:
forming the first electrodes on the base substrate, and forming at least one curved slit in each of the first electrodes.

10. The method according to claim 8, wherein
forming the first electrodes on the base substrate includes:
forming a plurality of gate lines on the base substrate;
forming a second insulating layer on the base substrate provided with the gate lines;
forming a plurality of data lines on the base substrate provided with the second insulating layer, the plurality of data lines being intersected with the plurality of gate lines; one pixel region being defined by any two adjacent data lines and any two adjacent gate lines intersected with the two adjacent data lines; a plurality of pixel regions being formed on the base substrate; and
forming the first electrodes on the base substrate provided with the data lines, each first electrode being disposed in one pixel region, and
forming the second electrodes on the base substrate provided with the first insulating layer and forming at least one curved slit in each of the second electrodes includes:
forming the second electrodes on the base substrate provided with the first insulating layer, forming at least one curved slit in each second electrode, and any two adjacent second electrodes being symmetrical relative to one of the gate lines or one of the data lines disposed between the two adjacent second electrodes.

11. The method according to claim 8, wherein
the slit is a semicircular slit; or
the slit is formed by two elongated slits of which one end is communicated, and an angle between the longitudinal directions of the two elongated slits is ranged from 150 to 178 degrees.

12. The method according to claim 8, wherein
each of the first electrodes is a pixel electrode, and each of the second electrodes is a common electrode; or
each of the first electrodes is a common electrode, and each of the second electrodes is a pixel electrode.

13. A display device, comprising: the display substrate according to claim 1.

14. The display device according to claim 13, wherein
at least one curved slit is formed in each of the first electrodes.

15. The display device according to claim 13, wherein
a plurality of gate lines is formed on the base substrate;
a second insulating layer is formed on the base substrate provided with the gate lines;
a plurality of data lines is formed on the base substrate provided with the second insulating layer, the plurality of data lines is intersected with the plurality of gate lines; one pixel region is defined by any two adjacent data lines and any two adjacent gate lines intersected with the two adjacent data lines; a plurality of pixel regions is formed on the base substrate;
the first electrodes are formed on the base substrate provided with the data lines, and each first electrode is disposed in one pixel region;
the first insulating layer is formed on the base substrate provided with the first electrodes; and
the second electrodes are formed on the base substrate provided with the first insulating layer, at least one curved slit is formed in each second electrode; each second electrode is disposed in one pixel region; and any two adjacent second electrodes are symmetrical relative to one of the gate lines or one of the data lines disposed between the two adjacent second electrodes.

16. The display device according to claim 13, wherein
the slit is a semicircular slit; or
the slit is formed by two elongated slits of which one end is communicated, and an angle between the longitudinal directions of the two elongated slits is ranged from 150 to 178 degrees.

17. The display device according to claim 13, wherein
each of the first electrodes is a pixel electrode, and each of the second electrodes is a common electrode; or
each of the first electrodes is a common electrode, and each of the second electrodes is a pixel electrode.

18. The display device according to claim 15, wherein
a plurality of curved slits is formed in each first electrode and the curved slits have a same shape; and an interval between every two adjacent slits is equal.

19. The display device according to claim 13, wherein
the display device is an LCD device; and the display substrate is an array substrate.
